(19) United States
(12) Patent Application Publication
(10) Pub. No.: US 2004/0036151 A1
(43) Pub. Date: Feb. 26, 2004

(54) DOUBLE LEADFRAME-BASED PACKAGING STRUCTURE AND MANUFACTURING PROCESS THEREOF

(76) Inventors: Chung-Liang Hsiao, Taipei (TW); Chih-Kung Huang, Yi-Lan (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/249,560

(22) Filed: Apr. 18, 2003

(30) Foreign Application Priority Data
Aug. 22, 2002 (TW) 91118967

(51) Int. Cl. H01L 23/495

(52) U.S. Cl. 257/666

(57) ABSTRACT

A packaging structure is constructed from a double-leadframe structure that comprises a first and a second leadframe stacked on each other. The first leadframe includes a plurality of first leads that respectively have first outer leads. The second leadframe includes a plurality of second leads that respectively extend into inner leads and second outer leads. The second leadframe is stacked on the first leadframe in a manner that the second outer leads are correspondingly placed over the first outer leads.

### BACKGROUND OF THE INVENTION

1. Field of the Invention

The invention relates generally to a packaging structure and, more particularly, to a packaging structure for an image sensor device.

2. Description of the Related Art

Currently known image taking equipment such as digital cameras or scanning apparatus usually include an image sensor that is capable of capturing image light and converting it to digital signals. The image sensor may typically be a charge coupled device (CCD) or a complementary metal oxide semiconductor (CMOS) image sensor.

FIG. 1 is a flow chart that schematically illustrates a manufacturing process of an image sensor packaging structure of the prior art, and FIG. 2 through FIG. 9 are schematic views illustrating the packaging structure at corresponding stages in the manufacturing process.

As illustrated in FIG. 1 and FIG. 2, one packaging structure known in the prior art is constructed from a leadframe 113 that is first fixedly attached (step 100) before undergoing molding (step 102). As illustrated in FIG. 8, the leadframe 113 comprises a down-set die pad 116 around which extend a plurality of leads 114, the die pad 116 being supported via one or more tie bar 132. Lower and upper surfaces of the leadframe 113, at an outer periphery, respectively include guide grooves 134, 136 by means of which the leadframe 113 is driven in movement during the manufacture process. Each of the leads 114 extends into an inner lead 114a and an outer lead 114b.

Referring to FIG. 3 and FIG. 9, within an encapsulation area 140 of the leadframe 113, a lower surface of the die pad 116, and lower lead surfaces and spacing gaps between the inner leads 114a are covered and filled with a first molding element 118a. An upper lead surface of each inner lead 114a is left exposed. Within the encapsulation area 140, a protruding ringed molding element 118b is further formed on the upper surface of the leadframe 113.

Referring to FIG. 4, after molding, all the exposed parts of the leadframe 113 undergo plating (step 104) to form a layer 120 of nickel-gold alloy thereon.

Referring to FIG. 5, a chip 122 is subsequently attached on the die pad 116 via an adhesive material 121, and wire bonding is performed to electrically connect bonding pads 124 of the chip 122 to the inner leads 114a via conductive wires 126 (step 106).

Referring to FIG. 6, the packaging structure is upwardly sealed via hermetically placing a transparent cover 130 on the molding element 118b (step 108) to allow light passage.

Referring to FIG. 7, each package unit is individualized via dicing, the protruding outer leads 114b being bent according to an N outline (step 110). The achieved package structure then undergoes testing (step 112). This testing is typically performed in a testing socket 138 where the electrical connection is established via the contact surface area L₁ of the N-outline outer leads 114b.

The performance of the manufactured packaging structure involves the consideration of several factors, including the bondability between the conductive wires and the inner leads, the solderability between the outer leads and the external connection members, and the adhesion of the molding compound with the leadframe. Plating of the leadframe 113 with nickel-gold alloy as described above is typically performed in order to obtain a better bondability and solderability of the leadframe. However, because it results in a poor adhesion of the molding elements 118a, 118b with the surface of the leadframe, this plating is therefore usually performed after molding. This post-plating step (referring to a plating step performed after molding) requires an additional repositioning of the leadframe on another working support, which needs additional conveyance. As a result, the processing sequence of the prior art increases the manufacturing cost, and further renders the automation of the manufacturing process more difficult to achieve. Furthermore, due to the N-outline outer leads, the final packaging structure may have an undesired height.

### SUMMARY OF THE INVENTION

An aspect of the invention is therefore to provide a double leadframe-based packaging structure that can overcome the above problems.

To achieve the above and other objectives, the invention provides a packaging structure that is constructed from a double-leadframe structure. The double-leadframe structure comprises a first leadframe and a second leadframe that is stacked on the first leadframe. The first leadframe comprises a plurality of first leads, each of which includes a first outer lead. The first leadframe is plated with a material layer such as a palladium layer that improves the solderability of the leadframe and its adhesion with a molding compound subsequently formed. The second leadframe comprises a plurality of second leads, each of which extends into an inner lead and a second outer lead. The inner leads of the second leadframe are respectively spot plated with a material layer such as a silver layer that improves the bondability of the inner leads. The second leadframe is stacked on the first leadframe with the second leads correspondingly placed over the first leads. Via molding, an encapsulant is formed to partially cover the double-leadframe structure. The encapsulant fills spacing gaps between the first leads, including a central area of the first leadframe from which radiate the first leads, and spacing gaps between the second leads. The encapsulant further forms a ringed projection on the second leadframe, enclosing a chip-mounting region that approximately corresponds to the central area of the first leadframe. The portion of the first and second leadframes exposed by the encapsulant comprises the inner leads of the first leadframe and a portion of the first and second outer leads. A chip is attached on the encapsulant in the chip-mounting region. The chip is electrically connected to the inner leads via a plurality of conductive wires. The chip is covered with a cover that is attached on the ringed projection of the encapsulant. Lastly, an individual package unit is formed via dicing through the outer peripheral regions of the first and second leads. Each final package unit then has outer connection members that are formed by the stack of the first and second outer leads of the first and second leadframes.

In accordance with the above features of the invention, the first and second leadframes respectively include a plurality of guide grooves by the alignment of which the first and second leadframes are stacked on each other.

In accordance with a variant embodiment of the invention, the first leadframe additionally includes a die pad within the chip-mounting region to which the chip is attached.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a flow chart schematically illustrating the manufacturing process of an image sensor package known in the prior art;

FIG. 2 through FIG. 7 are schematic views of a packaging structure at corresponding stages in the manufacturing process of the prior art illustrated in FIG. 1;

FIG. 8 is a top planar view of FIG. 2;

FIG. 9 is a top planar view of FIG. 3;

FIG. 10 is a flow chart schematically illustrating the manufacturing process of a packaging structure according to an embodiment of the invention

FIG. 11 through FIG. 16 are schematic views of a packaging structure at corresponding stages in the manufacturing process of the invention illustrated in FIG. 10;

FIG. 17 is a top planar view of the second leadframe 213 of FIG. 11;

FIG. 18 is a top planar view of the first leadframe 313 of FIG. 11;

FIG. 19 is a top planar view of FIG. 12;

FIG. 20 is a top planar view of FIG. 13; and

FIG. 21 is a schematic view of a packaging structure fabricated according to a variant embodiment of the invention.

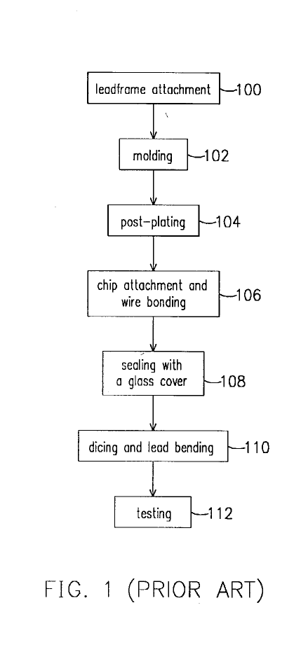

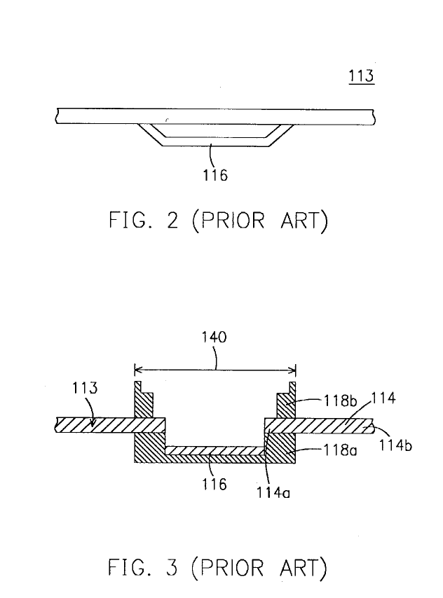

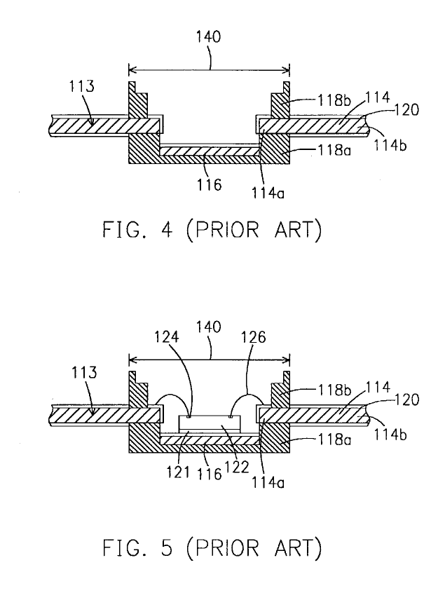

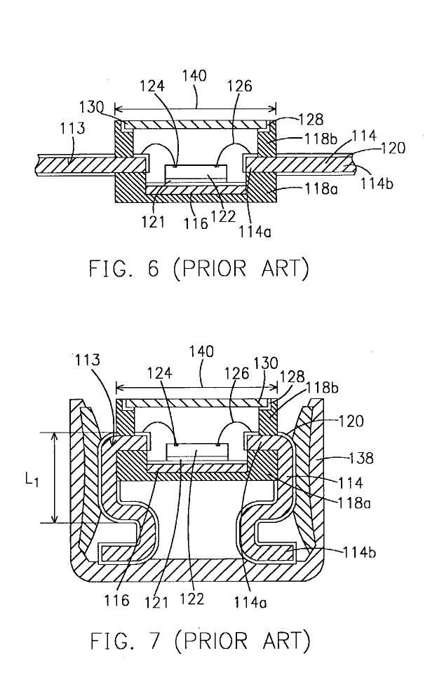

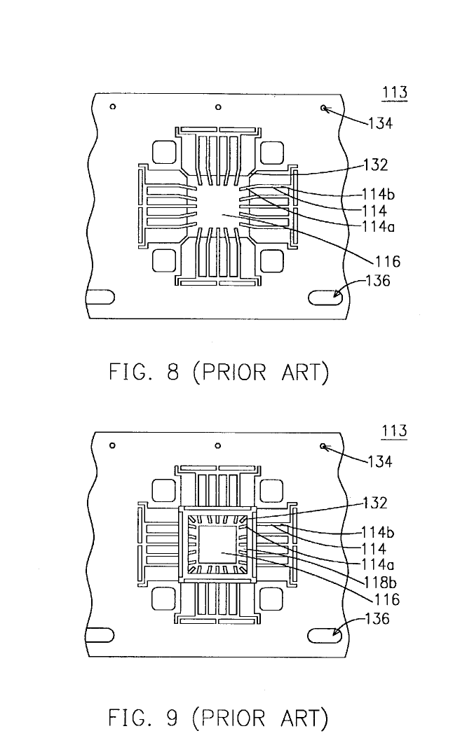

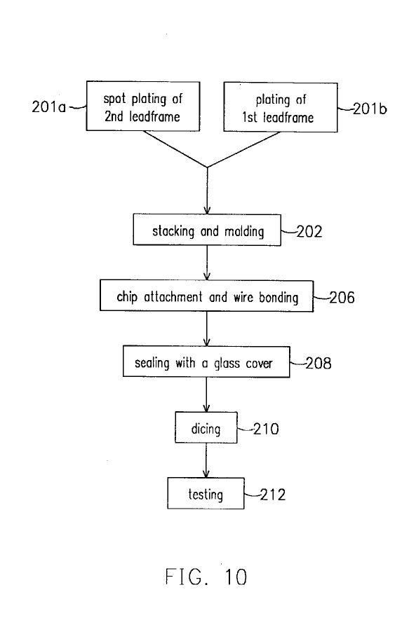

### DETAILED DESCRIPTION

The following detailed description of the embodiments and examples of the present invention with reference to the accompanying drawings is only illustrative and not limiting. Furthermore, wherever possible in the description, the same reference symbols will refer to similar elements and parts unless otherwise illustrated in the drawings.

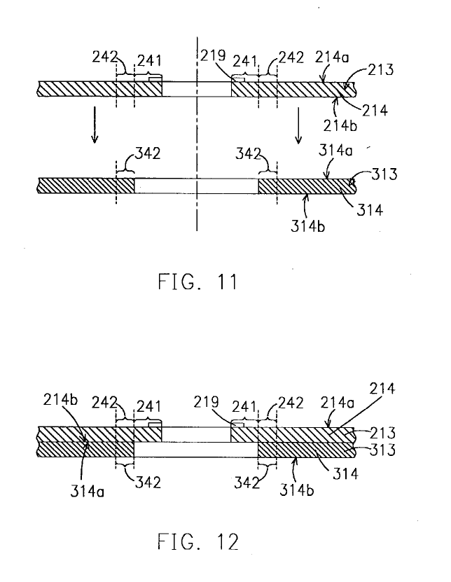

Reference now is made to FIG. 10 in conjunction with FIG. 11 through FIG. 21 to describe the manufacturing process of a packaging structure according to an embodiment of the invention. This embodiment will refer to an image sensor packaging structure, but it will be understood that this specific embodiment should not be construed in a manner to limit the scope of the invention that may be suitable for packaging different types of integrated circuit (IC) chips.

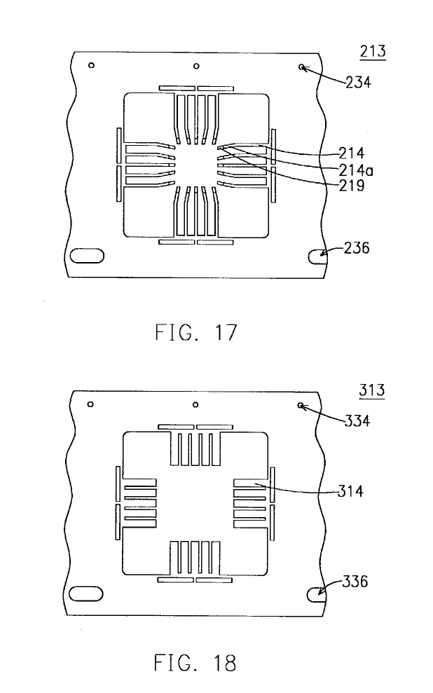

As illustrated in FIG. 10 and FIG. 11, the packaging structure is constructed from a double-leadframe structure that comprises a first leadframe 313 and a second leadframe 213. The first leadframe 313, made of, for example, nickel-iron alloy, copper alloy or other base metal, is externally plated with a material layer (step 201b) that improves the solderability of the leadframe and its adhesion with a molding compound. This plating layer preferably includes, but is not limited to, a palladium layer. An interface material, comprising copper, nickel, silver, nickel-palladium or other adequate alloys, is further preferably interposed between the plating palladium layer and the base metal of the first leadframe 313. The first leadframe 313 comprises a plurality of first leads 314, each of which has an upper lead surface 314a and a lower lead surface 314b and terminates in a first outer lead 342. As illustrated in the planar top view of FIG. 18, the first leadframe 313, at an outer periphery, further includes a plurality of guide grooves 334, 336 that are formed through its upper and lower surfaces, through which the first leadframe 313 is driven in movement during the manufacturing process.

The second leadframe 213 comprises a plurality of second leads 214, each of which includes an inner lead 241 and a second outer lead 242. Each of the second leads 214 of the second leadframe 213 has an upper lead surface 214a and a lower lead surface 214b. Selected spots on the upper lead surfaces 214a of the inner leads 241 are respectively plated with a material layer that improves the bondability of the inner leads 241 (step 201a). This plating layer preferably includes, but is not limited to, a silver layer 219. As illustrated in the planar top view of FIG. 17, the second leadframe 213, similar to the first leadframe 313, peripherally includes a plurality of guide grooves 234, 236.

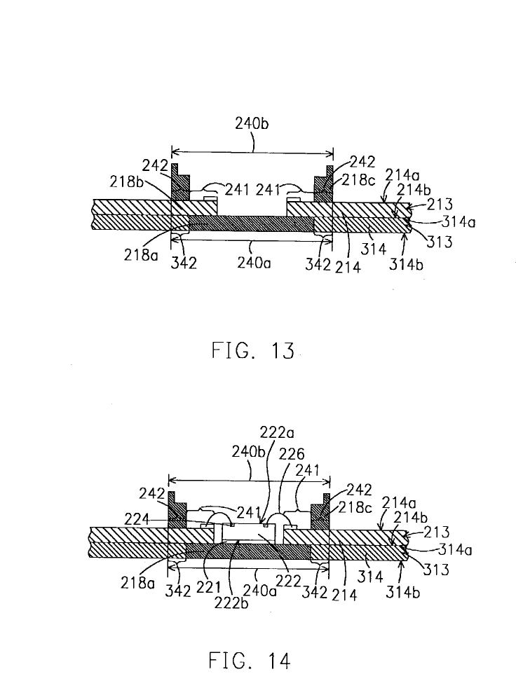

Referring to FIG. 10, FIG. 12, FIG. 13 and FIG. 19, stacking and molding steps 202 are performed. The first leadframe 313 and the second leadframe 213 are stacked on each other by alignment of their respective guide grooves 334, 336 and 234,236. The second leads 214 are thereby placed correspondingly over the first leads 314, and more particularly, the second outer leads 242 are correspondingly arranged over the first outer leads 342.

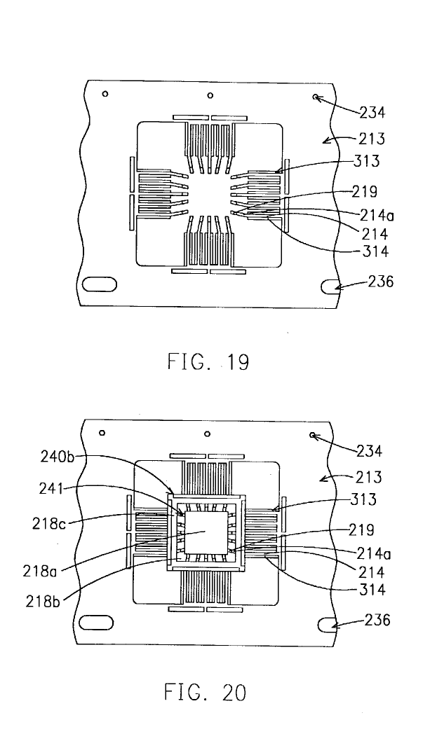

Referring to FIG. 13 and FIG. 19, an encapsulant is formed via molding to partially cover the double-leadframe structure. The formed encapsulant comprises a first molding element 218a, a second molding element 218b, and a third molding element 218c. Within an encapsulation area 240a of the first leadframe 313, the first molding element 218a fills spacing gaps between the first leads 314, including a central area from which radiate the first leads 314, and exposes the lower lead surface 314b of the first leadframe 313. The second molding element 218b (see FIG. 20) fills spacing gaps between second leads 214 within an encapsulation area 240b of the second leadframe 213, and exposes the upper lead surface 214a of the second leads 214. The third molding element 218c is shaped in a ringed projection in the encapsulation area 240b. The third molding element 218c encloses a chip-mounting region that approximately corresponds to the central area of the encapsulation area 240a. As it is better seen in the planar top view of FIG. 20, the third molding element 218c protrudes over the second leadframe 213 according to, for example, a parallelepiped contour, and upwardly extending into a step-profiled top end for facilitating the mount of a cover thereon as described hereafter. The above encapsulant is formed from a molding compound that includes, but is not limited to, epoxy.

Via plating 201b of the first leadframe 313, the solderability of the first leadframe 313 and the adhesion of the encapsulant, including the first, second, and third molding elements 218a, 218b, 218c, on the first leadframe 313 are both promoted.

Referring to FIG. 10 and FIG. 14, chip attachment and wire bonding steps 206 are performed. Via an adhesive material 221, the rear surface 222b of a chip 222 is attached on the first molding element 218a in the chip-mounting region. Bonding pads 224 formed on the active surface 222a of the chip 222 are electrically connected to the inner leads 241 of the second leadframe 213 via a plurality of conductive wires 226. The chip 222 may include, for example, complementary metal oxide semiconductor (CMOS) devices, and the conductive wires 226 may include, for example, gold or aluminum wires. Via spot plating 201a applied on the inner leads 241 of the second leadframe 213, the bondability between the inner leads 241 and the conductive wires 226 is promoted.

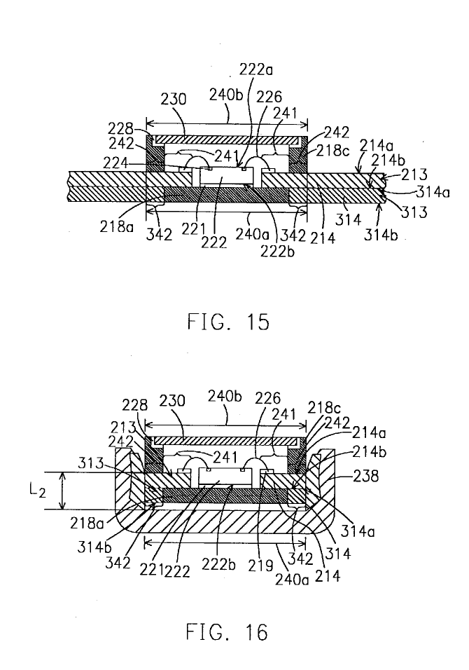

Referring to FIG. 10 and FIG. 15, a sealing step 208 is performed. Via an adhesive material 228, a transparent cover 230, made of, for example, glass material, is hermetically sealed on the stepped top end of the third molding element 218c to allow the capture of image light.

Referring to FIG. 10 and FIG. 16, the first and second leadframes 313, 213 then are diced (step 210) to form an individual package unit. The individual package unit is formed via dicing through the outer peripheral regions of the first and second outer leads 342, 242, including the molding elements 218a, 218b, 218c. Each final package unit then has outer connection members that are formed by the stack of the first and second outer leads 342, 242.

The achieved package unit then undergoes testing (step 212) by insertion in a testing socket 238 where the electrical connection of the package unit is established through the stacked first and second outer leads 342, 242. Being formed by stacking of the outer leads of both leadframes, the contact surface area L₂ provided by the outer connection members of the package unit is therefore sufficient to effectively establish electrical connection, and no lead bending step is needed. As a result, the general height of the package unit is reduced and the manufacturing process, without lead bending, is more economical.

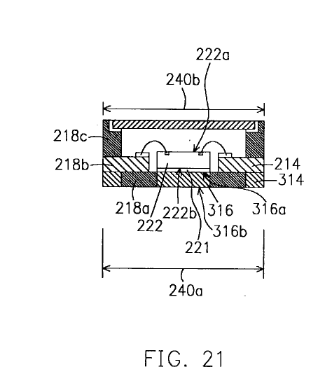

Now referring to FIG. 21, a schematic view illustrates another embodiment of the invention. The embodiment of FIG. 21 differs from the previous embodiment in that the first leadframe 313 additionally includes a die pad 316, located within the encapsulation area 240a, around which extend the leads 314. The first molding element 218a covers the spacing gaps between the leads 314 while exposing the lower surfaces of the leads 314 and the upper and lower surfaces 316a, 316b of the die pad 316. The rear surface 222b of the chip 222 is attached on the die pad 316 via an adhesive material 221. The other elements of the embodiments of FIG. 21 are similar to those of the embodiment of FIG. 21.

As described above, the invention therefore provides a packaging structure that achieves good bondability, good solderability, and good adhesion between the leadframe structure and the molding compound. Meanwhile, the conveyance of the packaging structure in the manufacturing process is reduced.

In one embodiment, the packaging structure is constructed from a double-leadframe structure that includes first and second leadframes. The first and second leadframes are separately plated and spot plated with respective plating layers to promote solderability, adhesion of the molding compound, and bondability of the double-leadframe structure with conductive wires. Furthermore, the outer connection members of the packaging structure being achieved via the stack of the outer leads of the first and second leadframes, the height of the packaging structure is therefore favorably reduced.

It should be apparent to those skilled in the art that other structures that are obtained from various modifications and variations of different parts of the above-described structures of the invention would be possible without departing from the scope and spirit of the invention as illustrated herein. Therefore, the above description of embodiments and examples only illustrates specific ways of making and performing the invention that, consequently, should cover variations and modifications thereof, provided they fall within the inventive concepts as defined in the following claims.

1. A double-leadframe structure for a semiconductor package, comprising:
a first leadframe, including a plurality of first leads; and
a second leadframe, including a plurality of second leads, each of the second leads extending into an inner lead and an outer lead, the second leadframe being stacked on the first leadframe by corresponding alignment of the second leads on the first leads.

2. The double-leadframe structure of claim 1, wherein the first leadframe is made of a base metal that is externally plated with a palladium layer, and an interface material is interposed between the base metal and the palladium layer, the interface material including copper, nickel, silver, and nickel-palladium.

3. The double-leadframe structure of claim 1, wherein the inner leads of the second leadframe are respectively spot plated with a silver layer.

4. The double-leadframe structure of claim 1, wherein a periphery of the first and second leadframes is respectively provided with a plurality of guide grooves by the alignment of which the first and second leadframes are correspondingly stacked on each other to have the first and second leads aligned with one another.

5. The double-leadframe structure of claim 2, wherein the base metal includes copper alloy or nickel-iron alloy.

6. The double-leadframe structure of claim 1, wherein the first leadframe further includes a die pad around which are arranged the first leads.

7. A double leadframe-based packaging structure, comprising:
a double-leadframe structure, including a first leadframe and a second leadframe that respectively have a plurality of first leads and second leads, each of the first leads extending into an inner lead and a first outer lead, and each of the second leads extending into a second outer lead, the first and second leadframes being stacked on each other with the second outer leads correspondingly placed on the first outer leads to form a plurality of outer connection members;
an encapsulant, filling a plurality of spacing gaps between the first and second leads, and forming a ringed projection on the second leadframe, while exposing the inner leads of the second leadframe and a portion of the first and second outer leads of the first and second leadframes, the ringed projection enclosing a chip-mounting region;
a chip, having a rear surface and an active surface, the active surface including a plurality of bonding pads and the rear surface being attached on a portion of the encapsulant in the chip-mounting region;
a plurality of conductive wires, respectively electrically connecting the bonding pads to the inner leads; and
a cover, attached on the ringed projection of the encapsulant.

8. The packaging structure of claim 7, wherein the chip and the cover are respectively attached to the encapsulant via an adhesive material.

9. The packaging structure of claim 7, wherein the first leadframe is made of a base metal that is externally plated with a palladium layer, and an interface material is interposed between the base metal and the palladium layer, the interface material including copper, nickel, silver, and nickel-palladium.

10. The packaging structure of claim 7, wherein the inner leads of the second leadframe are respectively spot plated with a silver layer.

11. The packaging structure of claim 9, wherein the base metal includes copper alloy or nickel-iron alloy.

12. The packaging structure of claim 7, wherein the encapsulant is made of epoxy.

13. The packaging structure of claim 7, wherein the first leadframe further includes a die pad around which extend the first leads of the first leadframe, the encapsulant exposing the die pad for the chip to be attached thereon via an adhesive layer.

14. The packaging structure of claim 7, wherein the conductive wires include gold wires or aluminum wires.

15. A method of fabricating a packaging structure, comprising:
providing a first leadframe that includes a plurality of first leads, each of the first leads extending into an inner lead and a first outer lead;
providing a second leadframe that includes a plurality of second leads, each of the second leads extending into a second outer lead;
stacking the second leadframe on the first leadframe with the second leads correspondingly placed over the first leads;
performing a molding process to form an encapsulant that fills spacing gaps between the first and second leads and forms a ringed projection on the second leadframe while exposing the inner leads of the second leadframe and a portion of the first and second outer leads of the first and second leadframes, the ringed projection enclosing a chip-mounting region;
attaching a chip on a portion of the encapsulant in the chip-mounting region;
electrically connecting the chip to the inner leads of the second leadframe via a plurality of conductive wires;
performing a sealing operation via attaching a cover on the ringed projection over the chip; and
performing a dicing operation to separate the packaging structure into an individual package unit.

16. The method of claim 15, wherein the first leadframe is made of a base metal that is further externally plated with a first material layer that promotes the solderability and the adhesion of the first leadframe with the encapsulant, and an interface material is interposed between the base metal and the first material layer.

17. The method of claim 16, wherein the first material layer includes a palladium layer and the interface material includes copper, nickel, silver, and nickel-palladium.

18. The method of claim 15, wherein the inner leads of the second leadframe are further respectively spot plated with a second material layer that promotes the bondability of the inner leads with the conductive wires.

19. The method of claim 18, wherein the second material layer includes a silver layer.

20. The method of claim 16, wherein the base metal includes copper alloy or nickel-iron alloy.

21. The method of claim 15, wherein the encapsulant is made of epoxy.

22. The method of claim 15, wherein the conductive wires include gold or aluminum wires.

23. The method of claim 15, wherein the cover is a transparent glass cover.

24. The method of claim 15, wherein the first leadframe further includes a die pad around which extend the first leads of the first leadframe, the encapsulant exposing the die pad for the chip to be attached thereon via an adhesive layer.
